(19) United States
(12) Patent Application Publication
(10) Pub. No.: US 2009/0151622 A1
(43) Pub. Date: Jun. 18, 2009

(54) SYSTEMS AND METHODS FOR GROWING POLYCRYSTALLINE SILICON INGOTS

(76) Inventor: Andrew B. Wilson, Lake Oswego, OR (US)

Correspondence Address: INTEL CORPORATION;c/o CPA Global, P.O. BOX 52050, MINNEAPOLIS, MN, 55402, US

(21) Appl. No.: 11/956,856

(22) Filed: Dec. 14, 2007

(51) Int. Cl. C30B 9/00

(52) U.S. Cl. 117/81; 117/206

(57) ABSTRACT

Systems and methods for growing polycrystalline silicon ingots are described. The systems and methods involve placing an initial charge of polysilicon in a crucible, using a direct solidification/heat exchanger method furnace to melt the initial charge to form a melt, and then introducing additional polysilicon to the melt while the melt and crucible are within the furnace. The additional polysilicon may be added to the crucible in order to bring the melt to any desired volume, including until the crucible is full or topped off. An augmenting mechanism, such as a hopper, may be used to introduce additional polysilicon to the melt. The hopper may have a silicon introduction controller that controls the introduction of polysilicon into the melt. Other embodiments are described.

### FIELD

This application relates generally to a system and method for growing polycrystalline silicon ingots.

### BACKGROUND

Directional solidification processes are known to be used to produce multi-crystal (or polycrystalline or polysilicon) wafers and ingots. These processes typically involve a casting process in which silicon is placed by hand into a quartz crucible that is substantially rectangular with a flat bottom. The crucible and silicon are then placed into a furnace environment where the silicon is often melted under an inert atmosphere. When the contents of the crucible, called the charge, have melted to a desired state of a molten silicon mass, called the melt, the bottom of the crucible as well as the charge contained within may be allowed to cool in a controlled manner. The cooling rate in this process is one factor that determines the final size of crystals in the ingots as well as the distribution of impurities. As the cooling occurs, one or more crystals may nucleate and grow upward. In this manner, the crystals may act to push impurities out of the expanding crystal microstructure.

### BRIEF DESCRIPTION OF THE DRAWINGS

The following description can be better understood in light of the Figures, in which:

FIG. 1 illustrates a partial cut-away view of some embodiments of an exemplary system for growing polycrystalline silicon ingots; and

FIG. 2 contains a flow chart illustrating some embodiments of an exemplary method for growing polycrystalline silicon ingots.

The Figures illustrate specific aspects of the systems and methods for growing polycrystalline silicon ingots. Together with the following description, the Figures demonstrate and explain the principles of the systems and methods for growing polycrystalline silicon ingots. In the drawings, the thickness of layers and regions are exaggerated for clarity. It will also be understood that when a layer is referred to as being “on” another layer or substrate, it can be directly on the other layer or substrate, or intervening layers may also be present. The same reference numerals in different drawings represent the same element, and thus their descriptions will not be repeated.

### DETAILED DESCRIPTION

The following description supplies specific details in order to provide a thorough understanding. Nevertheless, the skilled artisan would understand that the systems and methods for growing polycrystalline silicon ingots can be implemented and used without employing these specific details. For example, while the description focuses on systems and methods for growing polycrystalline silicon ingots, it can be modified to be used in other crystal growing systems and methods, whether or not they are used to make ingots.

In current manufacturing process for producing polycrystalline silicon ingots, when the silicon has been placed into the crucible, voids may be present between the pieces of silicon. And since liquid silicon tends to be denser than solid silicon, as the silicon melts in the crucible, the voids diminish, the silicon becomes denser, and the silicon loses its volume. For instance, a crucible that was filled almost completely with an initial charge of solid silicon may only be filled to about 75% of the volume of the crucible once the silicon is melted. Additionally, because silicon is denser as a liquid than it is as a solid, silicon tends to expand as it cools. This expansion tends to destroy the expensive quartz crucible. And because the melt in a crucible may not completely fill the crucible, the polycrystalline silicon ingots produced per furnace cycle may tend be smaller than possible and require a high total energy input per kilogram of polycrystalline silicon ingot.

The systems and methods for growing polycrystalline silicon ingots described herein allows additional solid raw-material silicon to be added in a controlled manner to a silicon melt that is within a crucible located in a heated furnace environment. In this manner, the volume of the melt in the crucible may be increased and/or topped off inside the heated furnace environment before the silicon ingot is cast. Thus, the systems and methods may produce larger ingots per crucible and per furnace cycle.

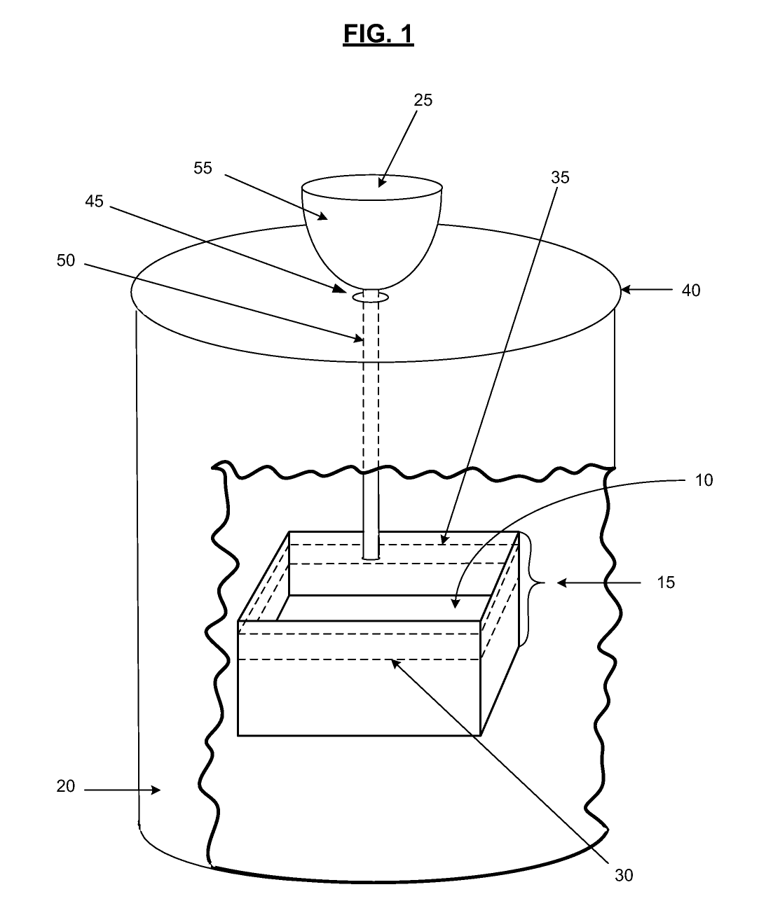

FIG. 1 illustrates some embodiments of the systems for growing polysilicon ingots. In FIG. 1, the system may comprise silicon (e.g., the melt 10), a crucible 15, a furnace 20, and an augmenter or augmenting mechanism (e.g., the hopper 25), which may add additional silicon to the melt 10.

The silicon may be added to crucible 15 as an initial solid silicon charge, as well as can be added to the crucible after the initial solid silicon charge has melted. In some embodiments, FIG. 1 illustrates that a solid charge of polysilicon has been added to the crucible 15 and heated to form a melt 10. In FIG. 1, a first dotted line 30 is used to indicate the volume of the melt 10 after the initial solid silicon charge has been melted. A second dotted line 35 in FIG. 1 illustrates the level of the melt 10 in the crucible 15 after additional silicon has been introduced.

The silicon may comprise any form of silicon that is suitable for the production of polysilicon ingots, including polysilicon that has been prepared through any known refining and/or preparing process. A non-limiting example of such processes includes a fluidized-bed reaction process. Some non-limiting examples of the forms of polysilicon that may be used include rod polysilicon, chunk polysilicon, chip polysilicon, and combinations thereof. In some embodiments, the polysilicon may be formed with a variety of diameters and attributes and used as the silicon introduced into the crucible 15.

In some embodiments, the rod polysilicon may be broken or cut into smaller, loose, polysilicon pieces, which may be classified as chunk polysilicon and/or chip polysilicon. Chunk polysilicon includes loose pieces of polysilicon that often may range from about 2 to about 20 centimeters across their largest dimensions. Chunk polysilicon may often possess an irregular shape and have sharp jagged edges. Generally, the sharp edges and irregular shape of chunk polysilicon may be the result of the severe mechanical impact or forces that can be used to break rod polysilicon into chunk polysilicon.

Chip polysilicon may be characterized as the loose pieces of polysilicon that are generally smaller than chunk polysilicon. In some instances, the chip polysilicon may have a flake-like shape. Often, chip polysilicon may comprise the debris that is left over when a polysilicon rod has been broken into chunk polysilicon.

Another form of polysilicon that may be utilized in the systems and methods described herein include bead polysilicon. Bead polysilicon may be characterized by a substantially uniform spherical shape or by its size. Generally, bead polysilicon tends to be smaller than chip polysilicon although their sizes may overlap in some embodiments. By way of example, typical bead polysilicon sizes may often range from about 0.5 to about 10 millimeters in diameter.

The system illustrated in FIG. 1 may comprise any crucible 15 that is suitable for the production of polycrystalline silicon ingots. Accordingly, the crucible 15 may be any shape or size that is suitable for use with a direct silicon solidification (DSS) or heat exchanger method (HEM) furnace 20. For example, the crucible 15 may be substantially rectangular, square, or cylindrical. FIG. 1 illustrates that, in some embodiments, the crucible 15 may be square or box-shaped with flat sides, a flat bottom, and corners that generally form right angles. One non-limiting example of a standard crucible 15 size and shape may include a 69 centimeter square crucible, or a crucible 15 that is about 69 centimeters long, about 69 centimeters wide, and about 42 centimeters tall. Another non-limiting example of a standard crucible 15 size and shape may include a 59 centimeter square crucible 15, or a crucible 15 that is about 59 centimeters long, about 59 centimeters wide, and about 39 centimeters tall.

The crucible 15 may also be made of any material suitable for use in a DSS or a HEM furnace 20. Some non-limiting examples of materials that may be used to form the crucible 15 may include quartz, graphite, silicon carbide, silicon nitride, aluminum oxide, mullite, and/or other materials capable of sustaining the extreme thermal demands that may be placed on the crucible 15. Indeed, in some embodiments, the crucible 15 may comprise quartz.

The system for making polysilicon ingots may comprise any known furnace suitable to melt silicon. FIG. 1 illustrates that one example of such a furnace may include a DSS or HEM furnace 20. The furnace 20 may have any characteristic suitable to allow additional silicon to be introduced into the crucible 15 while located within the furnace 20. For example, the furnace 20 may define an opening that allows additional silicon to be added to the crucible 15 when the crucible 15 is disposed within the furnace 20. Such an opening may have any characteristic and be located in any position that allows additional silicon to be introduced into the crucible 15 while tit is disposed within the furnace 20. FIG. 1 illustrates that, in some embodiments, the top 40 of the furnace 20 may define an opening 45. The opening 45 may have any desired characteristic, including any suitable shape and size. In some embodiments, as shown in FIG. 1, the opening 45 may be shaped and sized to fit around a hopper tube 50. However, in other embodiments, the opening 45 may be much larger so that the top 40 of the furnace 20 is substantially open or uncovered.

The system may also include an augmenting mechanism or augmentor for introducing additional silicon to the melt 10 while the melt 10 is disposed within the furnace 20. The augmenting mechanism may comprise any component that allows the mechanism to introduce additional silicon into the crucible 15 while it is located within the furnace 20. FIG. 1 illustrates that, according to some embodiments, the augmenting mechanism may comprise a hopper 25.

The hopper 25 may have any feature that allows it to add additional silicon to the crucible 15. The hopper 25 and any of its constituent components may be made of any suitable heat resistant material. For instance, the hopper 25 may be made of quartz, graphite, silicon carbide, silicon nitride, aluminum oxide, mullite, and/or other materials capable of withstanding the thermal demands associated with the process for making polysilicon ingots.

FIG. 1 illustrates some components that may be contained in the hopper 25, including a hopper chamber 55 and a hopper tube 50. Nevertheless, the hopper 25 may comprise additional components that are not shown in FIG. 1, including a silicon introduction controller. The chamber 55 receives silicon before some or all of it is added to the melt 10. The chamber 55 can be configured with any shape or size that allows it to receive the silicon and pass it from the chamber 55 to the melt 10 through the hopper tube 50. Some non-limiting examples of suitable chamber shapes may include a cone-like shape, a funnel-like shape, a partially spherical appearance, or the like. FIG. 1 illustrates that in some embodiments, the chamber 55 may have a partially spherical shape that acts to funnel silicon to an opening at the bottom of the chamber 55.

As shown in FIG. 1, the hopper 25 may have a hopper tube 50 that directs silicon to the melt 10 within the crucible 15. The tube 50 may have any desired characteristic that allows the tube 50 to direct the silicon to the melt 10. For example, the tube 50 may be any suitable size, diameter, and length. In some embodiments, the diameter of the tube 50 may be used to limit the amount of silicon that may be added to crucible 15 in a given period of time. Moreover, in some embodiments, the length of the tube 50 may allow the chamber 55 to be located outside of the furnace 20 as illustrated.

In some embodiments, the hopper 25 may also comprise a silicon introduction controller (or control mechanism) that may control the introduction of silicon from the chamber 55 to the melt 10 in the crucible 15. Indeed, the control mechanism may control the introduction of silicon in several ways. For example, the control mechanism may control the amount of polysilicon that is introduced to the crucible 15, the time when the silicon is added, the speed at which the silicon is added, etc. . . . Any mechanism that may control the introduction of silicon into the crucible 15 may be used with the hopper 25. Some non-limiting examples of such control mechanisms may include a valve that allows silicon to pass from the chamber 55 to the crucible 15 when the valve is open; a rotor that feeds silicon from the chamber 55 to the crucible 15 as the rotor turns; a conveyor belt that drops polysilicon into the chamber 55 at a desired time and speed; an auger conveyor that adds silicon to the chamber 55 when and as desired; a gate that opens to allow silicon to pass from the chamber 55 to the melt 10; and so forth.

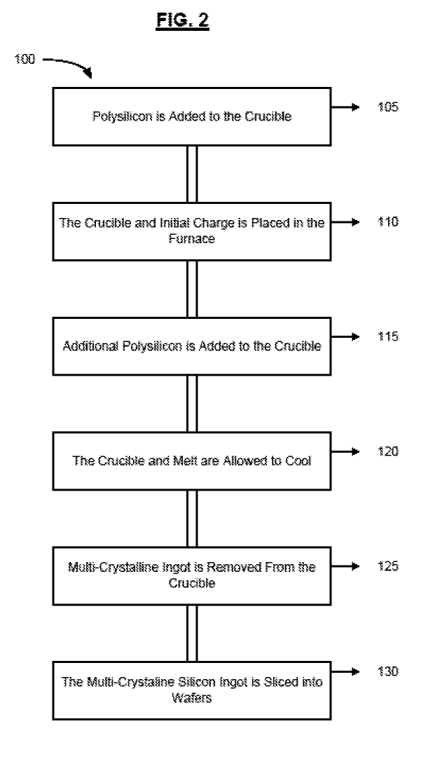

The methods for growing polycrystalline silicon ingots may be implemented using many different methods, including the exemplary method 100 shown in FIG. 2. Block 105 in FIG. 2 shows that a polysilicon suitable for producing a polycrystalline silicon ingot may be added the crucible 15. Generally, the initial silicon charge placed in the crucible 15 may comprise chunk and/or bead silicon, as described above. The polysilicon may be added to the crucible 15 in any suitable manner, including manually or using an automated loading process.

Block 110 of FIG. 2 illustrates that after the initial charge has been added to the crucible 15, the crucible 15 may be placed into the furnace 20 environment, where the initial charge may be melted. As the initial charge melts, its volume often decreases. For example, the dotted line 30 in FIG. 1 illustrates that an initial charge, which once may have filled the crucible 15, may only fill about 75% of the volume of the crucible 15 after the initial charge has melted.

Next, at 115, FIG. 2 shows that additional polysilicon may be added to the melt 10. This introduction of additional silicon to the melt 10 within the furnace 20 may be accomplished in any suitable method. For example, FIG. 1 illustrates that the hopper 25 may be used to add additional polysilicon to the melt 10 in a controlled manner. In this embodiment, additional solid raw-material polysilicon, such as bead or small particle chunk polysilicon that may melt quickly, may be added to the melt 10 through the hopper 25.

The additional polysilicon may be added to the melt 10 so that the volume of the melt 10 is increased to any desired volume. For example, FIG. 1 illustrates that additional polysilicon may be added to the melt 10 until the melt 10 substantially fills the crucible 15, as is illustrated by dotted line 35. As the additional polysilicon is added to the melt 10, it may be allowed to liquefy so the melt 10 becomes substantially homogeneous.

Block 120 of FIG. 2 illustrates that after the volume of the melt 10 has been increased and/or the crucible 15 has been topped off, the crucible 15 and the final melt 10 may be allowed to cool in a controlled manner. Typically, this cooling process begins at the bottom of both the crucible 15 and melt 10 and then continues to move up upwards.

At block 125 in FIG. 2, after the melt 10 has cooled and a solid polycrystalline ingot has been cast, the ingot may be removed from the crucible 15 in any appropriate manner. Finally, at block 130, the ingot may be sliced or cut into wafers in any desired manner. The polycrystalline silicon wafers may then be used as desired.

The systems and methods described above can be used to increase and/or top off the volume of the melt 10 from the initial charge while the melt 10 and crucible 15 are within the furnace 20. Where the initial silicon charge is melted to form a melt that is as low as about 0.01%, about 50%, or even from about 60 to 90% from of the volume of the crucible 15, the described method and system may be used to increase the volume of the melt from the initial charge to as much as about 100% or more of the volume of the crucible 15. Thus, larger polycrystalline ingots may be produced per crucible 15, as well as per furnace cycle, thereby reducing the cost of each crucible 15 per kilogram of cast ingot.

Having described the preferred aspects of the systems and associated methods, it is understood that the appended claims are not to be limited by particular details set forth in the above description, as many apparent variations thereof are possible without departing from the spirit or scope thereof.

1. A system for growing polysilicon ingots, comprising:
a crucible adapted to receive an initial charge of polysilicon;
a furnace adapted to receive the crucible and melt the initial charge of polysilicon to form a polysilicon melt; and
an augmentor adapted to introduce additional polysilicon into the polysilicon melt while the melt and the crucible are within the furnace.

2. The system of claim 1, wherein the furnace defines an opening for receiving the augmentor.

3. The system of claim 2, wherein the augmentor comprises a hopper.

4. The system of claim 3, wherein the hopper comprises a chamber and a tube.

5. The system of claim 1, wherein the augmentor comprises a silicon introduction controller.

6. The system of claim 5, wherein the silicon introduction controller comprises a gate, a valve, a rotor, a conveyor belt, or an auger conveyor.

7. The system of claim 1, wherein the crucible comprises a quartz crucible.

8. The system of claim 1, wherein the augmentor is adapted to introduce the additional polysilicon into the polysilicon melt until the crucible is topped off by the additional polysilicon.

9. A method for growing polysilicon ingots, comprising:
adding an initial charge of polysilicon to a crucible;
placing the initial charge and crucible into a furnace;
melting the initial charge of polysilicon to form a polysilicon melt;
adding additional polysilicon to the melt while the melt and crucible are within the furnace; and
allowing the crucible to cool.

10. The method of claim 9, wherein the additional polysilicon is added to the polysilicon melt by using an augmentor.

11. The method of claim 10, wherein the augmentor comprises a hopper.

12. The method of claim 11, wherein the hopper comprises a silicon introduction controller.

13. The method of claim 12, wherein the silicon introduction controller comprises a gate, a valve, a rotor, a conveyor belt, or an auger conveyor.

14. The method of claim 11, wherein the furnace defines an opening for receiving the hopper.

15. The method of claim 9, wherein adding additional polysilicon to the polysilicon melt comprises topping off the crucible with the additional polysilicon.
